(19) United States
(12) Patent Application Publication
(10) Pub. No.: US 2024/0364308 A1
(43) Pub. Date: Oct. 31, 2024

(54) COMPOSITE FILTER DEVICE

(71) Applicant: Murata Manufacturing Co., Ltd., Nagaokakyo-shi (JP)

(72) Inventor: Hiroyuki YOSHIOKA, Nagaokakyo-shi (JP)

(21) Appl. No.: 18/636,326

(22) Filed: Apr. 16, 2024

(30) Foreign Application Priority Data
Apr. 26, 2023 (JP) 2023-072186

(51) Int. Cl. H03H 9/56; H03H 9/13; H03H 9/54; H03H 9/70

(52) U.S. Cl. CPC H03H 9/568; H03H 9/133; H03H 9/542; H03H 9/70

(57) ABSTRACT

A composite filter device includes a piezoelectric substrate, a first filter defining and functioning as a band pass filter and including a longitudinally coupled resonator acoustic wave filter located on the piezoelectric substrate, and a second filter including at least one resonator and an inductor connected to a reference potential. When an area inside an outer periphery of the inductor in a plan view is defined as an inductor area, at least a portion of the inductor area and the longitudinally coupled resonator acoustic wave filter overlap each other in the plan view. The composite filter device further includes a shield electrode located between the inductor and the longitudinally coupled resonator acoustic wave filter without being connected to a signal potential and the reference potential, and the shield electrode overlaps an entirety of the inductor area in the plan view.

### CROSS REFERENCE TO RELATED APPLICATIONS

This application claims the benefit of priority to Japanese Patent Application No. 2023-072186, filed on Apr. 26, 2023. The entire contents of this application are hereby incorporated herein by reference.

### BACKGROUND OF THE INVENTION

### 1. Field of the Invention

The present invention relates to composite filter devices.

### 2. Description of the Related Art

Known composite filter devices including an acoustic wave resonator have been widely used as filters for a mobile phone. International Publication No. 2013/141183 discloses an example of an acoustic wave splitter serving as a composite filter device. This acoustic wave splitter includes two band pass filters. The two band pass filters are both connected to an antenna terminal. More specifically, the two band pass filters are a transmission filter chip and a reception filter chip. The transmission filter chip and the reception filter chip are flip-chip mounted on the circuit board.

The circuit board includes multiple dielectric layers. An inductor is disposed through the multiple dielectric layers. The inductor is connected between an antenna terminal and a ground potential. The inductor is used for impedance matching. In a plan view, the inductor overlaps a transmission filter chip and a reception filter chip.

In the acoustic wave splitter described in International Publication No. 2013/141183, the position where the reception filter chip or the transmission filter chip is mounted is more likely to vary. Thus, a positional relationship between a longitudinally coupled resonator acoustic wave filter included in the reception filter chip and an inductor on the circuit board is also more likely to vary. Thus, electromagnetic coupling between the inductor and the longitudinally coupled resonator acoustic wave filter may vary. This electromagnetic coupling affects out-of-band attenuation of the band pass filter. The acoustic wave splitter may fail to fully reduce variation of the out-of-band attenuation of the band pass filter.

### SUMMARY OF THE INVENTION

Example embodiments of the present invention provide composite filter devices each able to reduce variation of out-of-band attenuation of a band pass filter.

A composite filter device according to an example embodiment of the present invention includes a piezoelectric substrate, a first filter defining a band pass filter and including a longitudinally coupled resonator acoustic wave filter on the piezoelectric substrate, and a second filter including at least one resonator and an inductor connected to a reference potential. When an area inside an outer periphery of the inductor in a plan view is defined as an inductor area, at least a portion of the inductor area and the longitudinally coupled resonator acoustic wave filter overlap each other in a plan view, and the composite filter device further includes a shield electrode not connected to a signal potential and the reference potential and located between the inductor and the longitudinally coupled resonator acoustic wave filter, and the shield electrode overlaps an entirety of the inductor area in a plan view.

Composite filter devices according to example embodiments of the present invention are each able to reduce variation of out-of-band attenuation of the band pass filter.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a composite filter device according to a first example embodiment of the present invention.

FIG. 2 is a schematic plan view of an acoustic wave device chip according to the first example embodiment of the present invention.

FIG. 3 is a schematic elevational cross-sectional view of the composite filter device according to the first example embodiment of the present invention.

FIG. 4 is a plan view of an electrode structure of a first layer of a mount substrate according to the first example embodiment of the present invention.

FIG. 5 is a plan view of an electrode structure of a second layer of the mount substrate according to the first example embodiment of the present invention.

FIG. 6 is a plan view of an electrode structure of a third layer of the mount substrate according to the first example embodiment of the present invention.

FIG. 7 is a plan view of an electrode structure of a fourth layer of the mount substrate according to the first example embodiment of the present invention.

FIG. 8 is a plan view of an electrode structure of a fifth layer of the mount substrate according to the first example embodiment of the present invention.

FIG. 9 is a perspective plan view of an electrode structure of a sixth layer of the mount substrate according to the first example embodiment of the present invention.

FIG. 10 is a schematic bottom view describing a positional relationship between a shield electrode, an inductor of a second filter, and a longitudinally coupled resonator acoustic wave filter of a first filter according to the first example embodiment of the present invention.

FIG. 11 is a graph of attenuation frequency characteristics of a first filter according to a comparative example in a wide frequency range.

FIG. 12 is a graph of attenuation frequency characteristics, around a pass band, of the first filter according to the comparative example.

FIG. 13 is a graph of attenuation frequency characteristics of a first filter according to the first example embodiment of the present invention in a wide frequency range.

FIG. 14 is a graph of attenuation frequency characteristics, around a pass band, of the first filter according to the first example embodiment of the present invention.

FIG. 15 is a graph of attenuation frequency characteristics of a second filter according to the comparative example in a wide frequency range.

FIG. 16 is a graph of attenuation frequency characteristics of a second filter according to the first example embodiment of the present invention in a wide frequency range.

FIG. 17 is a schematic elevational cross-sectional view describing variation of the position at which an acoustic wave device chip is mounted.

FIG. 18 is a schematic plan view of the longitudinally coupled resonator acoustic wave filter according to the first example embodiment of the present invention.

FIG. 19 is a schematic bottom view describing the positional relationship between a shield electrode, an inductor of a second filter, and a longitudinally coupled resonator acoustic wave filter of a first filter according to a first modification of the first example embodiment of the present invention.

FIG. 20 is a schematic circuit diagram of a composite filter device according to a second modification of the first example embodiment of the present invention.

### DETAILED DESCRIPTION OF THE EXAMPLE EMBODIMENTS

The present invention is clarified by describing specific example embodiments of the present invention below with reference to the drawings.

Example embodiments described herein are merely examples, and components between different example embodiments may be replaced by each other, or combined with each other.

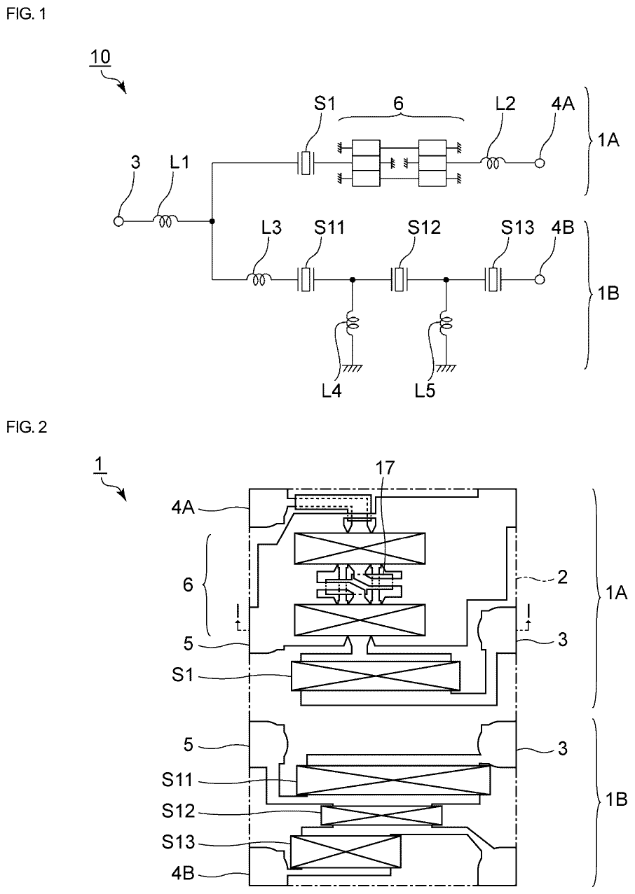

FIG. 1 is a circuit diagram of a composite filter device according to a first example embodiment of the present invention.

A composite filter device 10 includes a common connection terminal 3, a first filter 1A, and a second filter 1B. The first filter 1A and the second filter 1B are connected to the common connection terminal 3 in common. The common connection terminal 3 is preferably an antenna terminal in the present example embodiment. The antenna terminal is connected to an antenna. An inductor L1 is connected between the common connection terminal 3 and the first filter 1A and the second filter 1B.

The first filter 1A is preferably a band pass filter. More specifically, the first filter 1A is, for example, preferably a reception filter. In contrast, the second filter 1B is preferably a band elimination filter. Thus, the composite filter device 10 is an extractor.

The first filter 1A includes a first signal terminal 4A, a longitudinally coupled resonator acoustic wave filter 6, an acoustic wave resonator S1, and an inductor L2. The longitudinally coupled resonator acoustic wave filter 6 is connected between the common connection terminal 3 and the first signal terminal 4A. In the present example embodiment, the longitudinally coupled resonator acoustic wave filter 6 includes a two-stage 3-IDT structure. The structure of the longitudinally coupled resonator acoustic wave filter 6 is not limited to the above. The acoustic wave resonator S1 is connected between the longitudinally coupled resonator acoustic wave filter 6 and the common connection terminal 3. The inductor L2 is connected between the longitudinally coupled resonator acoustic wave filter 6 and the first signal terminal 4A.

The second filter 1B includes a second signal terminal 4B, multiple acoustic wave resonators, and multiple inductors. More specifically, the multiple acoustic wave resonators of the second filter 1B are, for example, preferably an acoustic wave resonator S11, an acoustic wave resonator S12, and an acoustic wave resonator S13. The acoustic wave resonator S11, the acoustic wave resonator S12, and the acoustic wave resonator S13 are connected to one another in series between the common connection terminal 3 and the second signal terminal 4B.

More specifically, the multiple inductors of the second filter 1B include an inductor L3, an inductor L4, and an inductor L5. The inductor L3 is connected between the common connection terminal 3 and the acoustic wave resonator S11. The inductor L4 is connected between the ground potential and a connection point between the acoustic wave resonator S11 and the acoustic wave resonator S12. The inductor L5 is connected between the ground potential and a connection point between the acoustic wave resonator S12 and the acoustic wave resonator S13. The circuit configuration of the composite filter device 10 is not limited to the above.

The first filter 1A is a band pass filter that outputs signals within a predetermined frequency band to the first signal terminal 4A, out of the signals input from the common connection terminal 3. The second filter 1B is a band elimination filter that outputs signals outside the predetermined frequency band to the second signal terminal 4B, out of the signals input from the common connection terminal 3. The first filter 1A and the second filter 1B are provided in a single acoustic wave device chip. The specific configuration of the composite filter device 10 is described below.

FIG. 2 is a schematic perspective plan view of an acoustic wave device chip in the first example embodiment. FIG. 2 schematically illustrates resonators each in a rectangle with two diagonals. The same applies to the following schematic plan views, schematic bottom views, and schematic cross-sectional views.

An acoustic wave device chip 1 of the composite filter device 10 includes a piezoelectric substrate 2. The piezoelectric substrate 2 is a substrate with piezoelectricity. In the present example embodiment, the piezoelectric substrate 2 is preferably a substrate simply including a piezoelectric material. Examples of a piezoelectric material include, for example, lithium tantalate, lithium niobate, zinc oxide, aluminum nitride, quartz, and titanate zirconate (PZT). The piezoelectric substrate 2 may be a multi-layer substrate including a piezoelectric layer if so desired.

Each resonator of the composite filter device 10 is located on the piezoelectric substrate 2. Each terminal of the composite filter device 10 is located on the piezoelectric substrate 2 as an electrode pad. The common connection terminal 3 of the first filter 1A and the common connection terminal 3 of the second filter 1B are located on the piezoelectric substrate 2. The two common connection terminals 3 are preferably uniformly located at portions other than portions on the piezoelectric substrate 2. Multiple reference potential terminals 5 are preferably located on the piezoelectric substrate 2. The reference potential terminals 5 are connected to the reference potential.

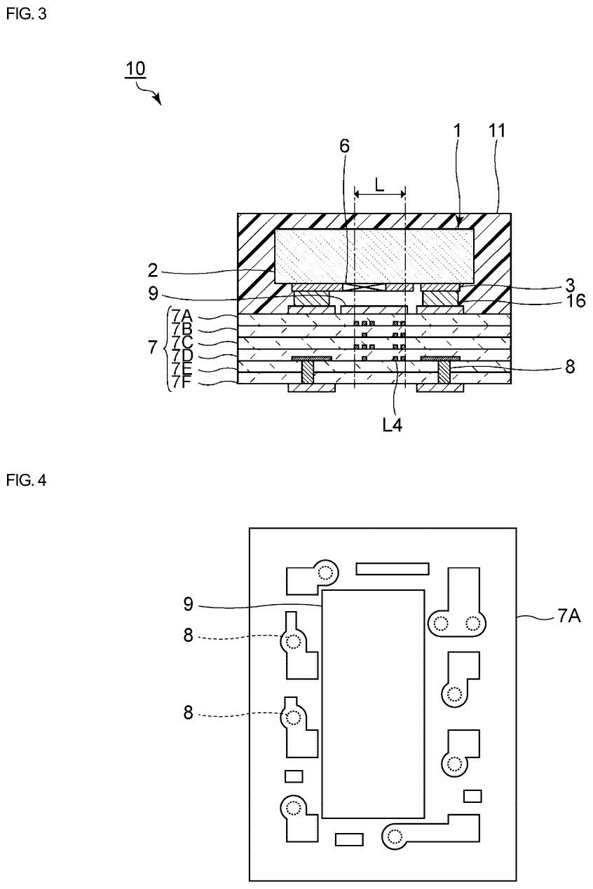

FIG. 3 is a schematic elevational cross-sectional view of a composite filter device according to the first example embodiment. FIG. 3 is a schematic cross-sectional view of a portion taken along line I-I in FIG. 2.

The composite filter device 10 includes a mount substrate 7. The acoustic wave device chip 1 is, for example, preferably flip-chip mounted on the mount substrate 7. The mount substrate 7 is preferably defined by a multilayer substrate including six layers. More specifically, the mount substrate 7 includes a first layer 7A, a second layer 7B, a third layer 7C, a fourth layer 7D, a fifth layer 7E, and a sixth layer 7F laminated in this order. Among these layers, the first layer 7A is located closest to the piezoelectric substrate 2. In the present example embodiment, each layer of the mount substrate 7 is a dielectric layer. Each of the layers may be formed from ceramics as appropriate. The mount substrate 7 may include any number of layers other than six layers.

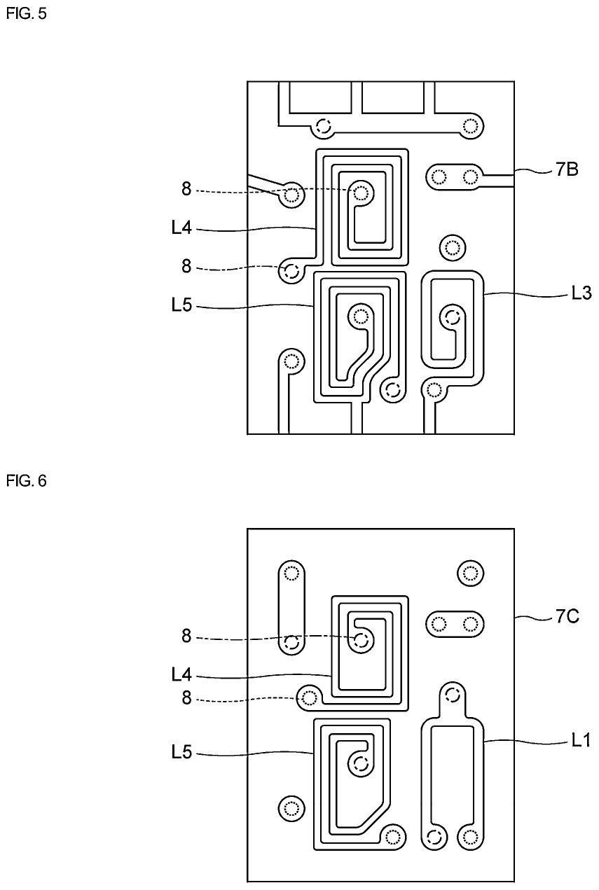

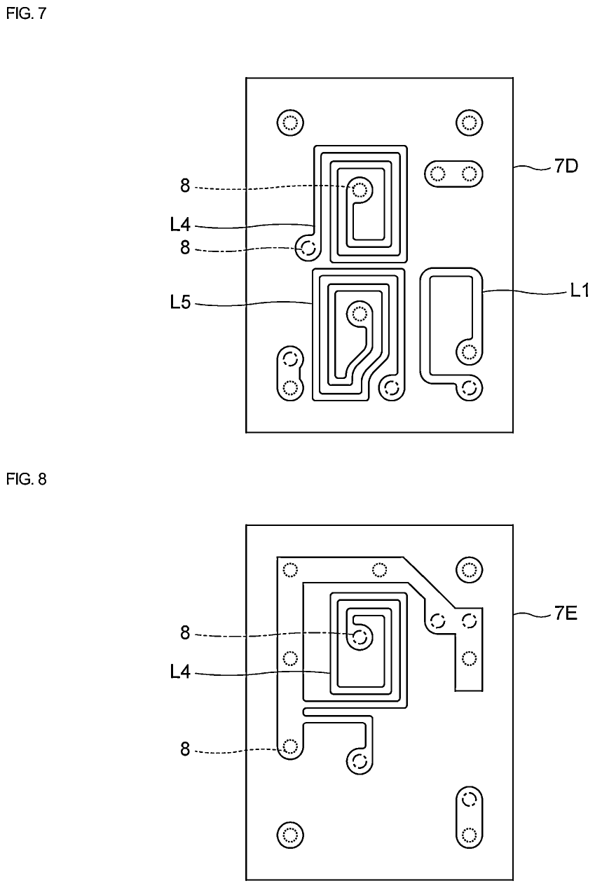

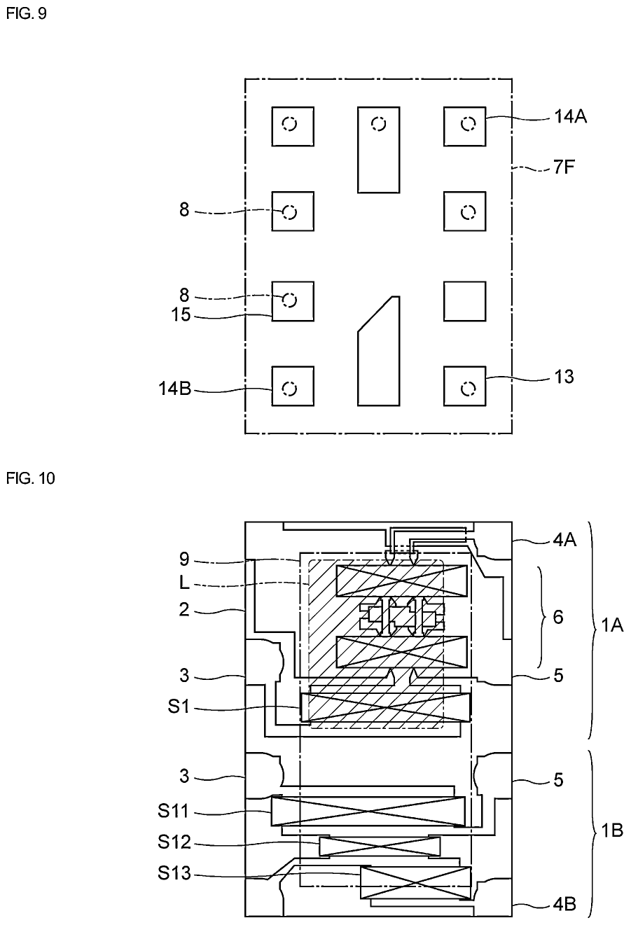

FIG. 4 is a plan view of an electrode structure of a first layer of a mount substrate according to the first example embodiment. FIG. 5 is a plan view of an electrode structure of a second layer of the mount substrate according to the first example embodiment. FIG. 6 is a plan view of an electrode structure of a third layer of the mount substrate according to the first example embodiment. FIG. 7 is a plan view of an electrode structure of a fourth layer of the mount substrate according to the first example embodiment. FIG. 8 is a plan view of an electrode structure of a fifth layer of the mount substrate according to the first example embodiment. FIG. 9 is a perspective plan view of an electrode structure of a sixth layer of the mount substrate according to the first example embodiment.

As illustrated in FIG. 4 to FIG. 9, a wiring electrode is located at each of the layers of the mount substrate 7. Multiple through electrodes 8 are disposed in the mount substrate 7. The wiring electrodes in the layers are electrically connected to one another through the through electrodes 8. A subset of the multiple wiring electrodes define an inductor in each of the first filter 1A and the second filter 1B. For example, as illustrated in FIG. 5 to FIG. 8, the inductor L4 of the second filter 1B extends through the second layer 7B, the third layer 7C, the fourth layer 7D, and the fifth layer 7E. Thus, the inductor L4 is a coil inductor.

As illustrated in FIG. 3, in a plan view, the area inside the outer periphery of the inductor L4 is defined as an inductor area L. In the present example embodiment, the inductor area L has a substantially rectangular shape in a plan view. In the plan view, the inductor area L and the longitudinally coupled resonator acoustic wave filter 6 overlap each other. In the plan view, at least a portion of the inductor area L and the longitudinally coupled resonator acoustic wave filter 6 overlap each other. Herein, a plan view is a view of the composite filter device 10 viewed from a side corresponding to an upper side in FIG. 3 to a side corresponding to a lower side. In contrast, a bottom view is a view of the composite filter device 10 viewed from a side corresponding to a lower side in FIG. 3 to a side corresponding to an upper side. In FIG. 3, of the piezoelectric substrate 2 and the mount substrate 7, the side closer to the piezoelectric substrate 2 is defined as an upper side, and the side closer to the mount substrate 7 is defined as a lower side.

A shield electrode 9 is located on the main surface of the first layer 7A of the mount substrate 7 closer to the acoustic wave device chip 1. The shield electrode 9 is located between the inductor L4 and the longitudinally coupled resonator acoustic wave filter 6. Thus, the shield electrode 9 overlaps the inductor area L in a plan view. The shield electrode 9 is connected to none of the signal potential and the reference potential. More specifically, the shield electrode is neither connected to a wire connected to the signal potential, nor connected to a wire connected to the reference potential. The shield electrode 9 may be formed from a single-layer metal film or multilayer metal film.

FIG. 10 is a schematic bottom view describing a positional relationship between a shield electrode, an inductor of a second filter, and a longitudinally coupled resonator acoustic wave filter of a first filter according to the first example embodiment. FIG. 10, which is a bottom view, is left-right inverted from a plan view, such as FIG. 2. In FIG. 10, the inductor area L is hatched.

In a plan view and a bottom view, the shield electrode 9 overlaps the entirety of the inductor area L. Hereinbelow, the outer peripheries of the shield electrode 9 and the inductor area L in the plan view and a bottom view are simply referred to as outer peripheries. In the present example embodiment, the outer periphery of the shield electrode 9 in the plan view is located outside the outer periphery of the inductor area L. Instead, at least a portion of the outer periphery of the shield electrode 9 may overlap the outer periphery of the inductor area L in the plan view.

Preferably, in the present example embodiment: 1) the shield electrode 9 is connected to none of the signal potential and the reference potential; 2) the shield electrode 9 is located between the inductor L4 and the longitudinally coupled resonator acoustic wave filter 6; and 3) the shield electrode 9 overlaps the entirety or substantially the entirety of the inductor area L in a plan view. Thus, the present example embodiment can reduce variation of out-of-band attenuation of the first filter 1A defining and functioning as a band pass filter. The above characteristics are described in detail through comparison between the present example embodiment and a comparative example.

A comparative example differs from the first example embodiment in that it includes no shield electrode. Five composite filter devices according to the first example embodiment and five composite filter devices according to the comparative example are prepared. The attenuation frequency characteristics of the first filter and the second filter in each of the above composite filter devices are measured.

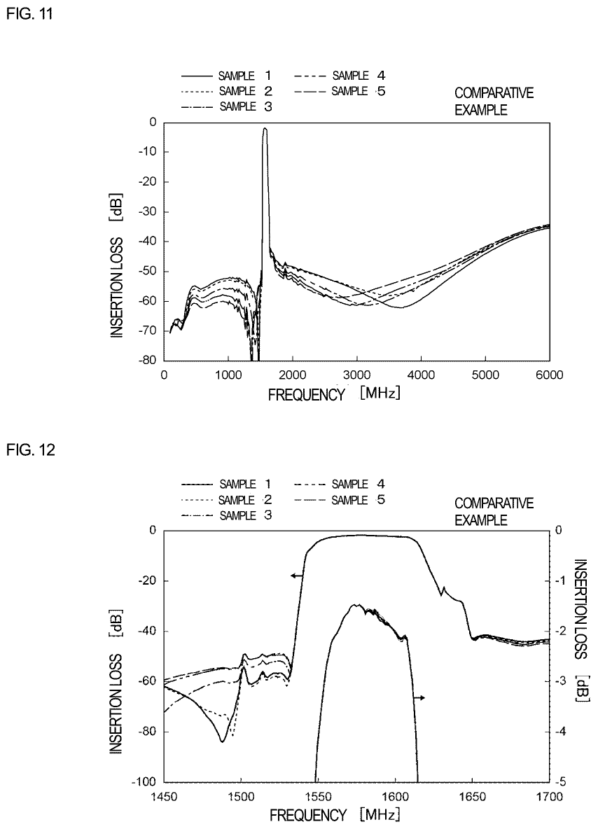

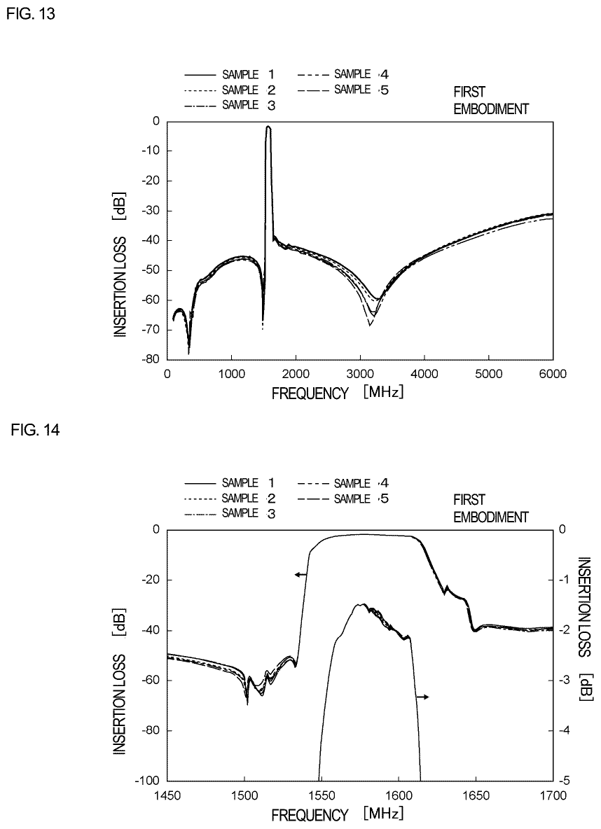

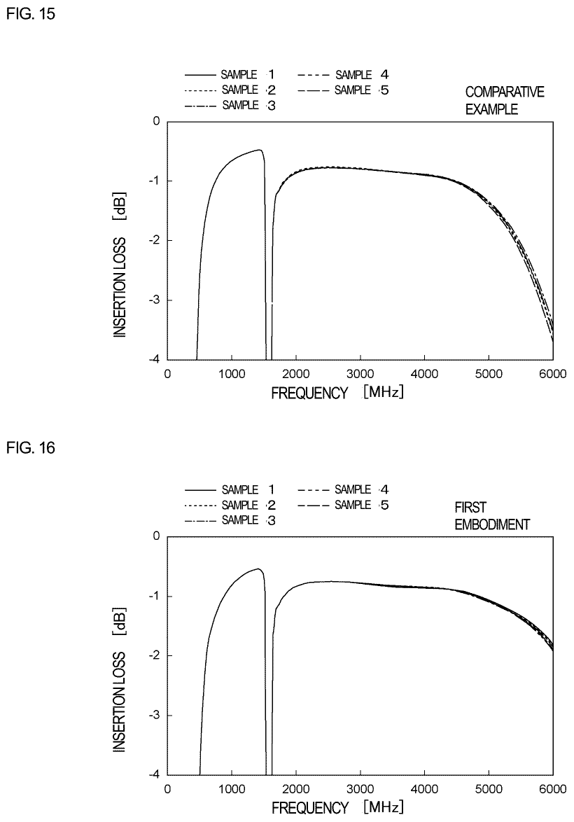

FIG. 11 is a graph of attenuation frequency characteristics of a first filter according to a comparative example in a wide frequency range. FIG. 12 is a graph of attenuation frequency characteristics, around a pass band, of the first filter according to the comparative example. FIG. 13 is a graph of attenuation frequency characteristics of a first filter according to the first example embodiment in a wide frequency range. FIG. 14 is a graph of attenuation frequency characteristics, around a pass band, of the first filter according to the first example embodiment. In FIG. 11 to FIG. 14, the composite filter devices are called samples 1 to 5. The same applies to FIG. 15 and FIG. 16 to be described below.

As illustrated in FIG. 11, in the comparative example, out-of-band attenuation largely varies. As illustrated in FIG. 12, out-of-band attenuation largely varies around the pass band in the comparative example, in a lower frequency range of the pass band. In contrast, as illustrated in FIG. 13 and FIG. 14, in the first example embodiment, out-of-band attenuation varies less in either a frequency range far from the pass band or around the pass band.

FIG. 15 is a graph of attenuation frequency characteristics of a second filter according to the comparative example in a wide frequency range. FIG. 16 is a graph of attenuation frequency characteristics of a second filter according to the first example embodiment in a wide frequency range.

As illustrated in FIG. 15 and FIG. 16, the first example embodiment and the comparative example have no large difference in the attenuation frequency characteristics of the second filter.

The reason why the first example embodiment can reduce variation of out-of-band attenuation of the first filter 1A serving as a band pass filter is as follows. When the acoustic wave device chip including a longitudinally coupled resonator acoustic wave filter is mounted on a mount substrate and an inductor is located at the mount substrate, electromagnetic coupling is more likely to occur between the inductor and the longitudinally coupled resonator acoustic wave filter. This electromagnetic coupling affects the out-of-band attenuation of the band pass filter. The electromagnetic coupling strength changes depending on the positional relationship between the inductor and the longitudinally coupled resonator acoustic wave filter.

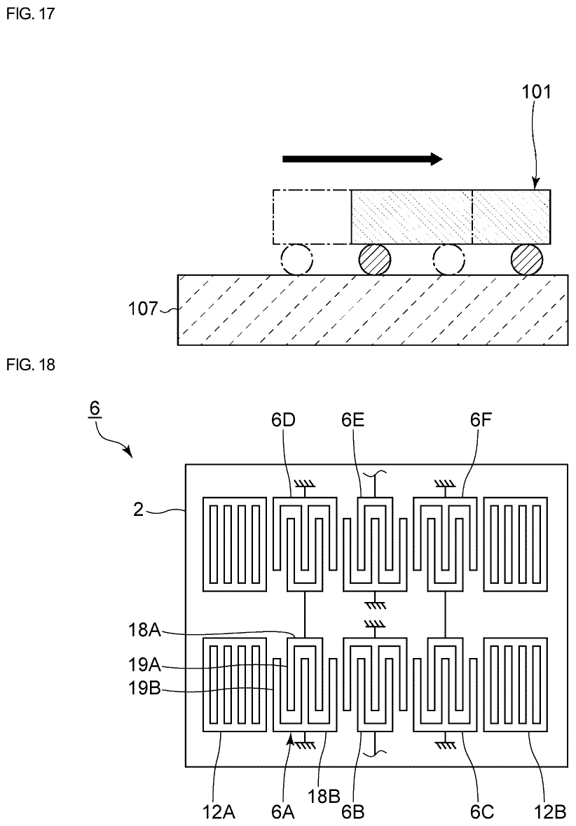

As schematically illustrated in FIG. 17, the position at which an acoustic wave device chip 101 is mounted on a mount substrate 107 is more likely to vary. Thus, positional relationship between the inductor and the longitudinally coupled resonator acoustic wave filter is also more likely to vary.

In the first example embodiment illustrated in FIG. 3, the shield electrode 9 is located between the inductor L4 and the longitudinally coupled resonator acoustic wave filter 6. The shield electrode 9 overlaps the entirety of the inductor area L in a plan view. Thus, electromagnetic coupling between the inductor L4 and the longitudinally coupled resonator acoustic wave filter 6 is reduced. Regardless of when the position at which the acoustic wave device chip 1 is mounted on the mount substrate 7 varies, the electromagnetic coupling strength is less likely to vary. Thus, the variation of the out-of-band attenuation of the first filter 1A serving as a band pass filter can be reduced.

In the first example embodiment, the shield electrode 9 is a floating electrode. The floating electrode is an electrode not connected to the signal potential and the reference potential. This structure can effectively reduce or prevent the effect on the out-of-band attenuation attributable to variation of the positional relationship between the inductor L4 and the longitudinally coupled resonator acoustic wave filter 6.

The structure of the first example embodiment is described below in further details.

FIG. 18 is a schematic plan view of the longitudinally coupled resonator acoustic wave filter according to the first example embodiment.

Multiple interdigital transducer (IDT) electrodes are located on the piezoelectric substrate 2. When an AC voltage is applied to the IDT electrodes, an acoustic wave is excited. As described above, the longitudinally coupled resonator acoustic wave filter 6 is a two-stage filter. In one stage, an IDT electrode 6A, an IDT electrode 6B, and an IDT electrode 6C are arranged in an acoustic wave propagation direction. In addition, a pair of a reflector 12A and a reflector 12B are positioned to hold these three IDT electrodes in between in the acoustic wave propagation direction. In another stage, similarly, an IDT electrode 6D, an IDT electrode 6E, an IDT electrode 6F, and a pair of reflectors are arranged. Each stage may include, for example, more than three IDT electrodes. For example, each stage may include, for example, five, seven, or nine IDT electrodes. Alternatively, the longitudinally coupled resonator acoustic wave filter 6 may be a single-stage filter.

The IDT electrode 6A includes a first busbar 18A, a second busbar 18B, multiple first electrode fingers 19A, and multiple second electrode fingers 19B. The first busbar 18A and the second busbar 18B face each other. First ends of the multiple first electrode fingers 19A are connected to the first busbar 18A. First ends of the multiple second electrode fingers 19B are connected to the second busbar 18B. The multiple first electrode fingers 19A and the multiple second electrode fingers 19B interdigitate with one another. The same applies to other IDT electrodes.

Each IDT electrode and each reflector may be made from a multilayer metal film or a single-layer metal film, for example. Herein, the first busbar 18A and the second busbar 18B may be collectively and simply described as busbars. The first electrode fingers 19A and the second electrode fingers 19B may be collectively and simply described as electrode fingers. The direction in which the multiple electrode fingers extend and the acoustic wave propagation direction are perpendicular or substantially perpendicular to each other.

In each IDT electrode, a first busbar is connected to the signal potential. A second busbar is connected to the reference potential. The busbar connected to the signal potential in the first stage and the busbar connected to the signal potential in the second stage are connected to each other. In the first example embodiment, each reflector is connected to the reference potential. Instead, each reflector may be left unconnected to the reference potential.

FIG. 2 schematically illustrates the longitudinally coupled resonator acoustic wave filter 6, including the multiple IDT electrodes and a pair of reflectors, in rectangles with two diagonals. As illustrated in FIG. 2, a wire connected to the reference potential and a wire connected to the signal potential partially oppose each other across an insulating film 17. The insulating film 17 electrically insulates the wires from each other. Thus, the area over which the wires are routed can be reduced, and the composite filter device 10 can have a reduced size. Instead, the insulating film 17 may be omitted.

Each acoustic wave resonator illustrated in FIG. 1 and FIG. 2 includes one IDT electrode and a pair of reflectors. The pair of reflectors are arranged to hold the IDT electrode in between in the acoustic wave propagation direction.

As illustrated in FIG. 3, the acoustic wave device chip 1 is preferably flip-chip mounted on the mount substrate 7. More specifically, each terminal located on the piezoelectric substrate 2 is joined to a corresponding terminal located at the first layer 7A of the mount substrate 7 with bumps 16. In addition, a sealing resin layer 11 is located on the mount substrate 7 to cover the acoustic wave device chip 1.

As illustrated in FIG. 2, the resonators including the longitudinally coupled resonator acoustic wave filter 6 of the first filter 1A and the resonators of the second filter 1B are preferably arranged on the same piezoelectric substrate 2. However, the resonators of the first filter 1A and the resonators of the second filter 1B may be arranged on different piezoelectric substrates if so desired. Thus, an acoustic wave device chip including the first filter 1A and an acoustic wave device chip including the second filter 1B may be mounted on the mount substrate 7.

The composite filter device 10 according to the first example embodiment preferably includes, for example, a chip size package (CSP) structure. However, the composite filter device 10 is not limited to this structure. For example, the composite filter device may also have a wafer level package (WLP) structure if so desired. When the composite filter device has a WLP structure, the structure may be any structure including an acoustic wave device chip having a hollow space. The structure may be any structure including multiple IDT electrodes arranged in the hollow space. The acoustic wave device chip may be mounted on, for example, the mount substrate 7 illustrated in FIG. 4. The sealing resin layer 11 may be located on the mount substrate 7 to cover the acoustic wave device chip.

More specifically, when the composite filter device has a WLP structure, for example, the acoustic wave device chip includes a support portion that is located on the piezoelectric substrate to surround the multiple IDT electrodes. The support portion has cavities. The multiple IDT electrodes are located in the cavities. A cover portion is preferably provided to cover the cavities of the support portion. The multiple IDT electrodes are disposed in a hollow space surrounded by the piezoelectric substrate, the support portion, and the cover member. Multiple through electrodes are disposed to extend through the cover member and the support portion. A first end of each through electrode is connected to a corresponding terminal on the piezoelectric substrate. Thus, an acoustic wave device chip is provided. Bumps are joined to a second end of each through electrode. The acoustic wave device chip is mounted on the mount substrate with multiple bumps.

As illustrated in FIG. 3, in the first example embodiment, the inductor L4 extends from the second layer 7B to the fifth layer 7E of the mount substrate 7. More specifically, as illustrated in FIG. 5, the inductor L4 preferably includes, for example, wire portions. The wire portion has, for example, a spiral shape. The through electrodes 8 are connected to the end portion of the wire portion. The wire portions of the inductor L4 illustrated in FIG. 5 to FIG. 8 are connected to one another with the through electrodes 8. Thus, the inductor L4 includes the multiple through electrodes 8. The multiple wire portions and the multiple through electrodes 8 form the inductor L4 with a coil shape.

The wire portion of each layer of the inductor L4 may have a shape of, for example, a straight line, a letter L, or a non-looped curve. Preferably, the wire portions of the multiple layers are connected to provide the inductor L4 as a coil-shaped inductor.

The first end of the inductor L4 is electrically connected to the reference potential terminals 5 with the bumps 16 and an electrode pad located at the first layer 7A illustrated in FIG. 3. The second end of the inductor L4 is connected to an external reference potential. More specifically, as illustrated in FIG. 9, a reference potential electrode 15 is located at the sixth layer 7F. The inductor L4 is connected to the reference potential with the reference potential electrode 15 in between.

A common connection electrode 13, a first signal electrode 14A, and a second signal electrode 14B are located at the sixth layer 7F. The common connection electrode 13 is electrically connected to the two common connection terminals 3 on the piezoelectric substrate 2 through the wires in the mount substrate 7, the through electrodes 8, and the bumps 16. Specifically, the two common connection terminals 3 are uniformized at the mount substrate 7. Similarly, the first signal electrode 14A is electrically connected to the first signal terminal 4A. The second signal electrode 14B is electrically connected to the second signal terminal 4B.

As illustrated in FIG. 3, preferably, the shield electrode 9 is located at the mount substrate 7. This structure has no need of disposing, for example, a portion including the shield electrode 9 at the mount substrate 7. Thus, providing this portion does not cause displacement of the shield electrode 9. This structure easily allows the entirety of the inductor area L and the shield electrode 9 to overlap each other in a plan view. The above structure can be more reliably and easily obtained regardless of when the shield electrode 9 has a reduced area. This structure can thus enhance size reduction and productivity.

The shield electrode 9 is preferably located on the surface of the mount substrate 7. The shield electrode 9 may be located in the mount substrate 7 between the inductor L4 and the longitudinally coupled resonator acoustic wave filter 6. For example, the inductor L4 may extend from the third layer 7C to the fifth layer 7E of the mount substrate 7, and the shield electrode 9 may be located between the first layer 7A and the second layer 7B.

The pass band of the first filter 1A and the attenuation band of the second filter 1B are in the same frequency range. Thus, the out-of-band attenuation of the first filter 1A can be increased. Instead, the pass band of the first filter 1A and the attenuation band of the second filter 1B may be in different frequency ranges.

Preferably, in the inductor L4, the magnetic field generated when current flows through the inductor L4 is directed from the piezoelectric substrate 2 toward the mount substrate 7. In a structure not including the shield electrode 9 according to the first example embodiment, electromagnetic coupling between the inductor L4 and the longitudinally coupled resonator acoustic wave filter 6 largely affects out-of-band attenuation. In contrast, the first example embodiment of the present invention can reduce the electromagnetic coupling. Thus, variation of out-of-band attenuation can be reduced. The present invention is thus particularly preferable when the inductor L4 with the above structure is to be used.

In the first example embodiment, in a plan view, the inductor L4 defining and functioning as a parallel inductor and the longitudinally coupled resonator acoustic wave filter 6 overlap each other. The shield electrode 9 is located between the inductor L4 and the longitudinally coupled resonator acoustic wave filter 6, and the shield electrode 9 overlaps the entirety of the inductor area L, which is an area inside the outer periphery of the inductor L4, in a plan view. In a plan view, the inductor L3 in the second filter 1B serving as a series inductor and the longitudinally coupled resonator acoustic wave filter 6 may overlap each other. The shield electrode 9 may be located between the inductor L3 and the longitudinally coupled resonator acoustic wave filter 6, and the shield electrode 9 may overlap the entirety or substantially the entirety of the inductor area, which is an area inside the outer periphery of the inductor L3, in a plan view. Also in this case, the variation of the out-of-band attenuation of the first filter 1A can be reduced.

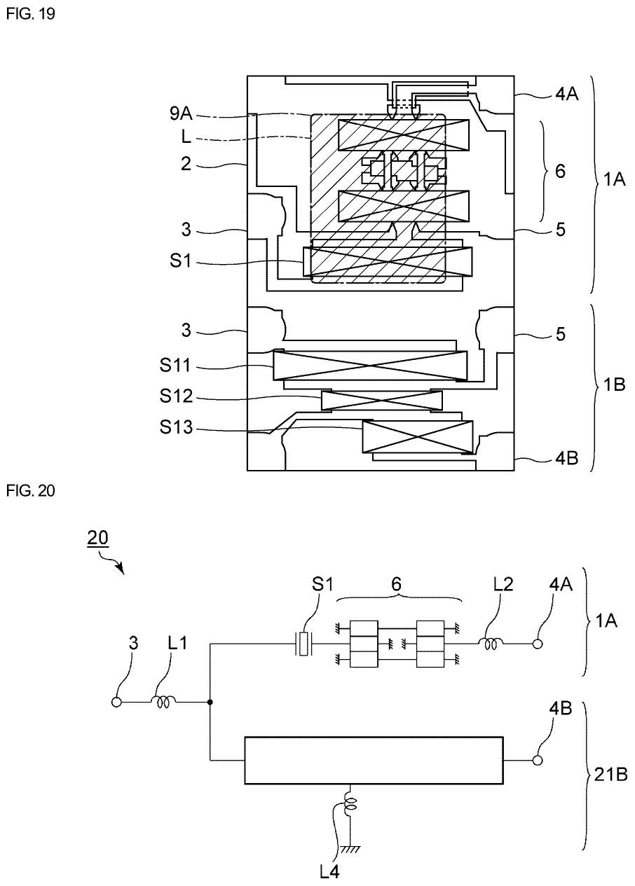

As illustrated in FIG. 10, in the first example embodiment, in a plan view, the outer periphery of the shield electrode 9 is located outside the outer periphery of the inductor area L. The shield electrode 9 may overlap the entirety or substantially the entirety of the inductor area L in a plan view. For example, in a first modified example of the first example embodiment illustrated in FIG. 19, the entirety or substantially the entirety of the outer periphery of a shield electrode 9A overlaps the outer periphery of the inductor area L in a plan view. This structure can also reduce electromagnetic coupling between the inductor L4 and the longitudinally coupled resonator acoustic wave filter 6. Thus, as in the first example embodiment, this modification can reduce variation of out-of-band attenuation of the first filter 1A. In addition, this modification can reduce the area of the shield electrode 9A, and thus can enhance size reduction of the composite filter device.

As described above, the composite filter device 10 is an extractor. However, this is not the only possible example. For example, in a second modified example of the first example embodiment schematically illustrated in FIG. 20, a second filter 21B is a band pass filter. The circuit configuration of the second filter 21B is not limited to a particular one except that it includes at least one resonator and includes the inductor L4 the same or substantially the same as that according to the first example embodiment. In a composite filter device 20 according to the present modified example, both of the first filter 1A and the second filter 21B are band pass filters.

As in the first example embodiment, the present modified example also includes the inductor L4. The first filter 1A and the shield electrode have the same or substantially the same structure as those in the first example embodiment. In the composite filter device 20, the shield electrode is connected to none of the signal potential and the reference potential. The shield electrode is located between the inductor L4 and the longitudinally coupled resonator acoustic wave filter 6. The shield electrode overlaps the entirety of the inductor area L in a plan view. This structure can thus reduce variation of out-of-band attenuation of the first filter 1A.

The two band pass filters of the composite filter device 20 may respectively be a transmission filter that outputs signals input from a transmission terminal to a common connection terminal, and a reception filter that outputs signals input from the common connection terminal to a reception terminal.

In the first example embodiment and each modified example of the first example embodiment, the composite filter device is an extractor or a duplexer, but these are not the only possible examples. A composite filter device according to the present invention may include at least one filter other than the first filter and the second filter. More specifically, a composite filter device may be a multiplexer including three or more filters including a band pass filter.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A composite filter device, comprising:
a piezoelectric substrate;
a first filter defining and functioning as a band pass filter and including a longitudinally coupled resonator acoustic wave filter on the piezoelectric substrate; and
a second filter including at least one resonator and an inductor connected to a reference potential; wherein
when an area inside an outer periphery of the inductor in a plan view is defined as an inductor area, at least a portion of the inductor area and the longitudinally coupled resonator acoustic wave filter overlap each other in the plan view; and
the composite filter device further includes a shield electrode not connected to a signal potential and the reference potential and located between the inductor and the longitudinally coupled resonator acoustic wave filter, and the shield electrode overlaps an entirety or substantially an entirety of the inductor area in the plan view.

2. The composite filter device according to claim 1, wherein the longitudinally coupled resonator acoustic wave filter of the first filter and the resonator of the second filter are located on the piezoelectric substrate in common.

3. The composite filter device according to claim 1, wherein the composite filter device is a duplexer.

4. The composite filter device according to claim 1, further comprising at least one filter other than the first filter and the second filter.

5. The composite filter device according to claim 1, wherein the second filter is a band elimination filter.

6. The composite filter device according to claim 5, wherein a pass band of the first filter and an attenuation band of the second filter are in a same or substantially a same frequency range.

7. The composite filter device according to claim 1, further comprising:
a mount substrate joined to the piezoelectric substrate with a bonding agent; wherein
the inductor is located at the mount substrate.

8. The composite filter device according to claim 1, further comprising a common connection terminal electrically connected to both of the first filter and the second filter.

9. The composite filter device according to claim 1, wherein the second filter includes an additional inductor connected to the reference potential.

10. The composite filter device according to claim 9, wherein the reference potential is a ground potential.

11. The composite filter device according to claim 8, wherein the second filter further includes:
an additional inductor connected to the reference potential; and
another additional inductor connected between the common connection terminal and the at least one resonator.

12. The composite filter device according to claim 1, wherein the at least one resonator is made from a multilayer metal film.

13. The composite filter device according to claim 1, wherein the at least one resonator is located on the piezoelectric substrate.

14. The composite filter device according to claim 1, further comprising a support portion located on the piezoelectric substrate to surround a portion of the longitudinally coupled resonator acoustic wave filter.

15. The composite filter device according to claim 1, wherein the second filter is a band pass filter.
